(19) United States
(12) Patent Application Publication
(10) Pub. No.: US 2010/0109720 A1
(43) Pub. Date: May 6, 2010

(54) SEMICONDUCTOR INTEGRATED CIRCUIT AND CONTROL METHOD OF THE SAME

(75) Inventor: Tatsuya NAKAGAWA, Ohtsu-shi (JP)

Correspondence Address: SUGHRUE MION, PLLC, 2100 PENNSYLVANIA AVENUE, N.W., SUITE 800, WASHINGTON, DC, 20037, US

(73) Assignee: NEC Electronics Corporation, Kawasaki (JP)

(21) Appl. No.: 12/575,118

(22) Filed: Oct. 7, 2009

(30) Foreign Application Priority Data
Oct. 30, 2008 (JP) 2008-279984

(51) Int. Cl. H03L 7/00

(52) U.S. Cl. 327/142

(57) ABSTRACT

A semiconductor integrated circuit according to an exemplary embodiment of the present invention includes a power-on-reset circuit that outputs a reset signal based on a detect signal representing that power is applied to the semiconductor integrated circuit; an initialization object circuit for which an initialization is performed based on the reset signal; and a power-on-reset monitor circuit that generates and outputs a power-on-reset monitor signal representing whether or not the initialization is performed normally, based on the reset signal output from the power-on-reset circuit and an output signal of the initialization object circuit for which the initialization is performed.

### BACKGROUND

1. Field of the Invention

The present invention relates to a semiconductor integrated circuit including a logic circuit which has a reset function, and a control method of the semiconductor integrated circuit.

2. Description of Related Art

When a semiconductor integrated circuit including a logic circuit starts up, an initialization needs to be performed at power-on of the integrated circuit. At the initialization of the semiconductor integrated circuit, the state of a signal, for example, the state of an output signal of the logic circuit is set to High or Low. Specifically, a data storage area and a setting circuit which determines data input/output direction for data transmission path need to be initialized by receiving a reset signal. Hereinafter, the logic circuit which needs to be initialized is called an initialization object circuit. For supplying the reset signal to the initialization object circuit, there are a method of supplying the reset signal from outside of the semiconductor integrated circuit, and a method of generating the reset signal by a power-on-reset generate circuit provided in the semiconductor integrated circuit and then inputting the generated reset signal to the initialization object circuit.

In the method of generating the reset signal in the semiconductor integrated circuit, when the semiconductor integrated circuit is configured not to output the reset signal to outside, the state of the generated reset signal cannot be observed from outside of the semiconductor integrated circuit. Therefore, only by observing the state of the initialization object circuit using an input/output port of the semiconductor integrated circuit, it can be determined whether or not the reset function is working properly at the power-on. Further, in this configuration incapable of outputting the reset signal to outside, even when a defect occurring in the initialization object circuits is detected by monitoring the input/output port, it cannot be determined whether the initialization object circuit has a defect or the power-on-reset circuit has a defect.

Japanese Unexamined Patent Application Publication No. 2002-43918 discloses a circuit configuration which can output an initialization completion judge signal representing whether or not the initialization of sequence circuits included in the semiconductor integrated circuit is performed completely. FIG. 12 shows part of the circuit disclosed in Japanese Unexamined Patent Application Publication No. 2002-43918. A power-on-rest signal generate unit 101 outputs a power-on-reset signal P_{ON} which sets an initial value to a flip-flop circuit 102. An initialization completion judge circuit 103 includes an initialization simulate circuit which simulates an initialization operation in the flip-flop circuit 102. The initialization completion judge circuit 103 detects that the initialization of the initialization simulate circuit is performed completely, and outputs an initialization completion signal RJ. The initialization completion signal RJ represents that the initialization in the flip-flop circuit is completed, and is output to the power-on-rest signal generate unit 101. When the power-on-rest signal generate unit 101 receives, for example, the initialization completion signal RJₙ which represents that the initialization of the final stage the flip-flop circuit 102 is finished, the power-on-rest signal generate unit 101 sets the power-on-reset signal P_{ON} to active signal level.

One input of a selector 104 receives the initialization completion signal RJₙ and another input of the selector 104 receives a data signal D_{OUT}. The selector 104 selects the initialization completion signal RJₙ or the data signal D_{OUT} based on a test signal TEST, and outputs the selected signal to a data/test common output terminal 105. In normal operation, the data signal D_{OUT} generated in the semiconductor integrated circuit is output to the data/test common output terminal 105. In test operation, by inputting the test signal TEST of the active level to the selector 104, the initialization completion signal RJ can be output through the data/test common output terminal 105.

### SUMMARY

The present inventor has found a problem that the circuit disclosed in Japanese Unexamined Patent Application Publication No. 2002-43918 can output either of the data signal D_{OUT} or the initialization completion signal RJₙ. Therefore, in order to judge whether a defect occurs in the power-on-reset circuit or in the initialization object circuit, both signals must be output respectively with switching output of the selector 104.

A first exemplary aspect of the present invention is a semiconductor integrated circuit which includes a power-on-reset circuit that outputs a reset signal based on a detect signal representing that power is supplied to the semiconductor integrated circuit; an initialization object circuit for which a initialization is performed based on the reset signal; and a power-on-reset monitor circuit that generates and outputs a power-on-reset monitor signal representing whether or not the initialization is performed normally, based on the reset signal output from the power-on-reset circuit and an output signal of the initialization object circuit for which the initialization is performed.

The present invention seeks to solve one or more of the above problems. Specifically, in the first exemplary aspect of the present invention, the power-on-reset monitor signal is generated based on the reset signal output from the power-on-reset circuit and the output signal of the initialization object circuit on which the initialization is performed. Accordingly, it can be determined whether the initialization object circuit has a defect or the power-on-reset circuit has a defect can be judged by monitoring the power-on-reset monitor signal.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a diagram showing an exemplary overall configuration of a semiconductor integrated circuit 100 according to a first exemplary embodiment of the present invention;

FIG. 2 is a diagram showing a specific example of an initialization object circuit 12 included in the semiconductor integrated circuit 100 according to the first exemplary embodiment of the invention;

FIG. 3 is a diagram showing terminals of sequence circuits 21 to 23 shown in FIG. 2 and a truth table;

FIG. 4 is a diagram showing part of FIG. 2, and showing an exemplary configuration of a combination circuit 25 in which an initial value is set independently of a pre-stage combination circuit 24;

FIG. 5 is a schematic diagram showing a relation between time and voltage for each of a source voltage, a reset signal Sᵣ, an output signal Sₒ of the initialization object circuit 12, an output signal of an inverter 131, and a power-on-reset monitor signal Sₘ;

FIG. 6 is a schematic timing chart showing a relation between time and voltage when the sequence circuit 21 which is the initialization object circuit 12 is broken;

FIG. 7 is a schematic timing chart showing a relation between time and voltage when the sequence circuit 21 which is the initialization object circuit 12 is broken;

FIG. 8 is a diagram showing an overall exemplary configuration of a semiconductor integrated circuit 200 according to a second exemplary embodiment of the present invention;

FIG. 9 is a diagram showing a specific configuration around the initialization object circuit provided in the semiconductor integrated circuit shown in FIG. 8;

FIG. 10 is a diagram showing operation of the semiconductor integrated circuit 200 according to the second exemplary embodiment of the present invention;

FIG. 11 is a diagram showing terminals of a sequence circuit 91 shown in FIG. 9 and a truth table; and

FIG. 12 is a diagram showing part of the circuit disclosed in Japanese Unexamined Patent Application Publication No. 2002-43918.

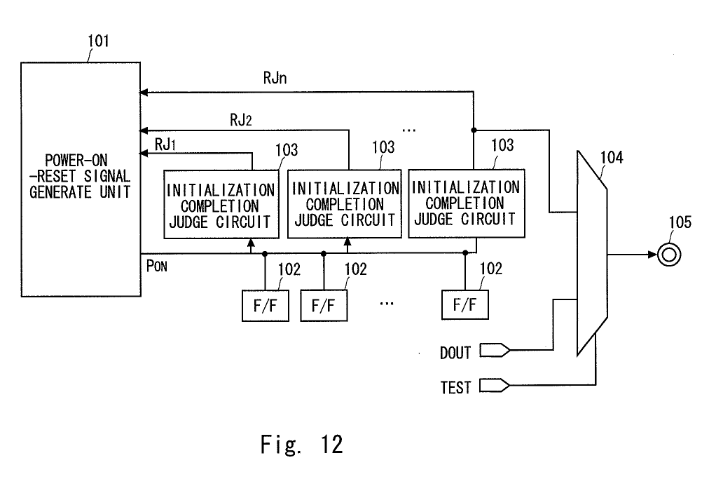

### DETAILED DESCRIPTION OF THE EXEMPLARY EMBODIMENTS

Hereinafter, preferred exemplary embodiments of the present invention will be described with reference to the accompanying drawings.

### First Exemplary Embodiment

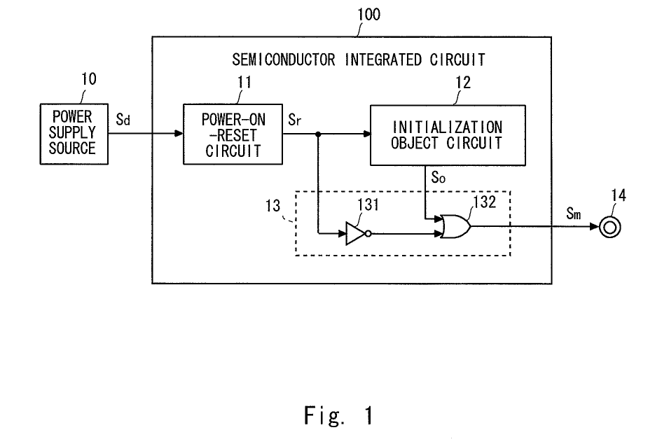

FIG. 1 shows an exemplary configuration of a semiconductor integrated circuit according to a first exemplary embodiment of the present invention. A semiconductor integrated circuit 100 according to an exemplary embodiment of the present invention includes a power-on-reset circuit 11, an initialization object circuit 12, and a power-on-reset monitor circuit 13.

The power-on-reset circuit 11 is configured to perform an initialization for the initialization object circuit 12 by outputting a reset signal Sᵣ to the initialization object circuit 12 at power-on of the semiconductor integrated circuit 100. The power-on-reset circuit 11 outputs the reset signal Sᵣ to the initialization object circuit 12 based on a detect signal S_{d} output from a power supply source 10 to detect the power-on of the semiconductor integrated circuit. The reset signal Sᵣ is for setting an initial value for the initialization object circuit 12.

The initialization object circuit 12 is an object circuit to be initialized at power-on of the semiconductor integrated circuit 100. The initialization object circuit 12 is a logic circuit including at least one sequence circuit. The initialization object circuit 12 is initialized in response to the reset signal Sᵣ received from the power-on-reset circuit 11.

The power-on-reset monitor circuit 13 is configured to generate a power-on-reset monitor signal Sₘ based on the reset signal Sᵣ received from the power-on-reset circuit 11. As described later, the state of the reset signal Sᵣ can be detected by monitoring the power-on-reset monitor signal Sₘ.

The power-on-reset monitor circuit 13 further receives an output signal Sₒ of the initialization object circuit 12 which has been initialized. The power-on-reset monitor circuit 13 generates the power-on-reset monitor signal Sₘ based on the reset signal Sᵣ and the output signal Sₒ. The power-on-reset monitor signal Sₘ is output for outside of the semiconductor integrated circuit 100 through an output function terminal 14 formed on the semiconductor integrated circuit 100.

The power-on-reset monitor circuit 13 includes an inverter 131 and a logical OR circuit 132. The inverter 131 inverts the signal state of the reset signal Sᵣ which is received from the power-on-reset circuit 11, and outputs the inverted signal to the logical OR circuit 132. One input of the logical OR circuit 132 receives an output of the inverter 131, and another input thereof receives the output signal Sₒ. The logical OR circuit 132 performs logical addition between the inverted reset signal Sᵣ and the output signal Sₒ, and outputs an added value to the output function terminal 14 as the power-on-reset monitor signal Sₘ.

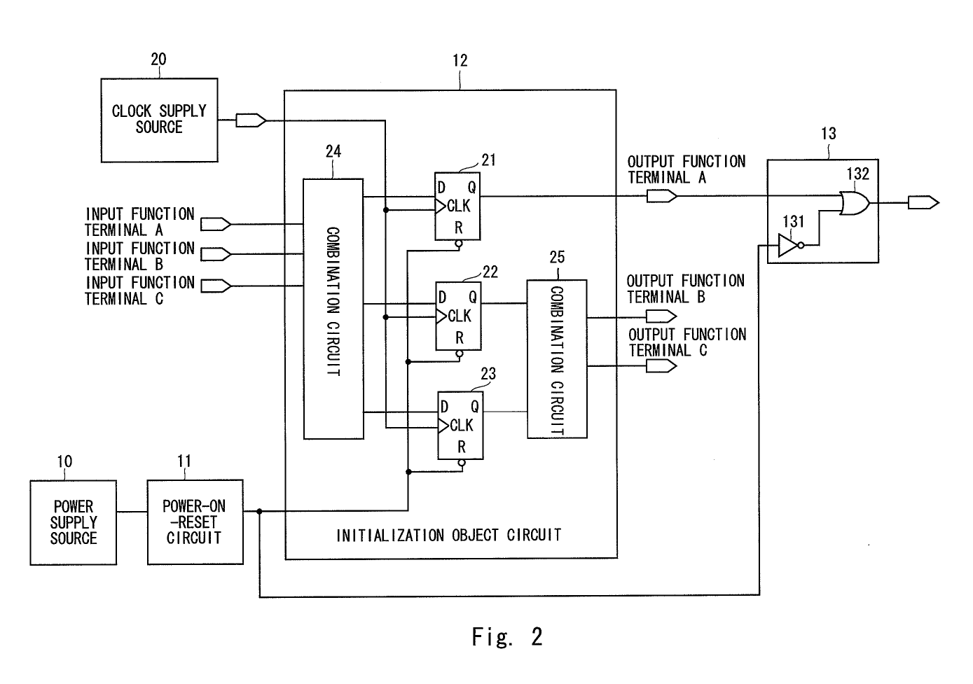

FIG. 2 shows a specific example of the initialization object circuit 12 included in the semiconductor integrated circuit 100 according to the first exemplary embodiment of the invention. The initialization object circuit 12 includes, for example, sequence circuits 21 to 23, and combination circuits 24 and 25. The sequence circuits 21 to 23 are circuits whose output is dependent on the previous state of the own circuit. The combination circuits 24 and 25 are circuits whose output is determined by the state of its input. For example, the sequence circuits 21 to 23 may be configured to include at least one of a flip-flop, a latch circuit, a counter, a register, and the like. Hereinafter, the sequence circuits are referred as the flip-flop circuits for ease of explanation.

The sequence circuits 21 to 23 are the flip-flop circuits having a data holding function for holding data and a reset function for resetting the stored data. The detailed configuration of the sequence circuits 21 to 23 will be described later. The combination circuits 24 and 25 are groups of logic gates whose output is determined by an arbitrary state of input terminals. The combination circuit 24 is configured as to output data to each data input terminal (D) of the sequence circuits 21 to 23 based on the state of the signal received from the input function terminals A to C. The input function terminals A, B, and C are signal input terminals receiving signals from the inside or outside of the semiconductor integrated circuit 100.

A clock supply source 20 generates clocks, and outputs the generated clocks to each clock input terminal (CLK) of the sequence circuits 21 to 23. The clock supply source 20 may be formed inside or outside of the semiconductor integrated circuit 100.

An output terminal (Q) of the sequence circuit 21 is connected to the output function terminal A. The logical OR circuit 132 receives the output of the sequence circuit 21 through the output function terminal A. The output terminal (Q) of the sequence circuit 22 and the output terminal (Q) of the sequence circuit 23 are connected with the combination circuit 25. The output side of the combination circuit 25 is connected to the output function terminals B and C. That is, the output function terminals A to C are arbitrary signal output terminals which state are dependent on pre-stage circuits.

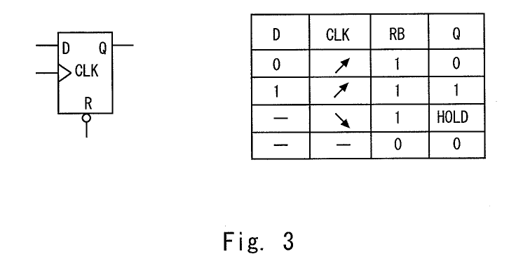

FIG. 3 is a diagram showing the terminals of the sequence circuits 21 to 23 and a truth table. The sequence circuits 21 to 23 shown in FIG. 3 are typical circuits of delay flip-flops called “D-FF” which generally includes a reset input. In FIG. 3, “D” represents an input terminal for receiving a data signal, “CLK” an input terminal for receiving a clock signal, “Q” an output terminal for outputting a data signal, and “RB” an input terminal for receiving negative logic of the reset signal Sᵣ.

The sequence circuits 21 to 23 have a function for holding the state of the data signal received from the input terminal D when the state of the clock signal CLK received from the input terminal CLK changes from Low to High, and outputting the held state to the output terminal Q. The sequence circuits 21 to 23 have another function for setting the output terminal Q to Low irrespective of the state of the data signal received from the input terminal D and the clock signal received from the input terminal CLK, when the state of the input terminal RB is Low.

Data input and data output in the sequence circuits 21 to 23 will be described specifically with reference to the truth table. When the reset signal RB is “1” (for example, High) and the received data signal D is “0” (for example, Low), the data signal Q “0” is output at the rising edge of the clock signal CLK. When the reset signal RB is “1” and the received data signal D is “1”, the data signal Q “1” is output at rising edge of the clock signal CLK. When the reset signal RB is “1” and the clock signal falls, the state which is set at the last rising edge is held at the falling edge of the clock signal CLK irrespective of the state of the input data signal D. When the reset signal RB is “0”, the data signal Q “0” is output irrespective of state of the clock signal CLK.

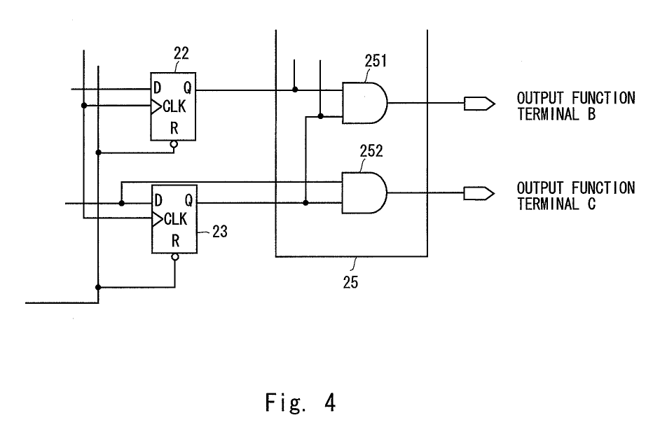

FIG. 4 is a diagram showing part of FIG. 2, and showing an exemplary configuration of the combination circuit 25 whose initial value is set irrespective of the pre-stage combination circuit 24. FIG. 4 shows only the combination circuit 25 and the pre-stage sequence circuits 22 and 23 shown in FIG. 2. The sequence circuits 22 and 23 are the flip-flop circuits which input and output are represented in the truth table in FIG. 3. The combination circuit 25 includes logical AND circuits 251 and 252.

One terminal of the logical AND circuit 251 receives the output signal Q of the sequence circuit 22, and another terminal thereof receives the output signal Q of the sequence circuit 23. The logical AND circuit 251 performs logical multiplication between the output signal Q of the sequence circuit 22 and the output signal Q of the sequence circuit 23, and outputs the multiplied value to the output function terminal B. One terminal of the logical AND circuit 252 receives the data signal D received from the pre-stage combination circuit 24 to the sequence circuit 23, and another terminal of the logical AND circuit 252 receives the output signal Q of the sequence circuit 23. The logical AND circuit 252 performs logical multiplication between the received these two signals, and outputs the multiplied value to the output function terminal C.

In this circuit configured as described above, when the power-on-reset circuit 11 normally functions at power-on of the semiconductor integrated circuit 100, the reset function operates for the sequence circuits 22 and 23. Accordingly, each of the output signals Q of the sequence circuits 22 and 23 becomes Low irrespective of the pre-stage combination circuit 24. Because both of input terminals of the logical AND circuit 251 receives Low level signals, a Low level signal is output to the output function terminal B of the logical AND circuit 251. Further, because one terminal of the logical AND circuit 252 receives Low level signal from the sequence circuit 23, Low level signal is output to the output function terminal C from the logical AND circuit 252 irrespective of the output of the pre-stage combination circuit 24 which is another input of the logical AND circuit 252. In this way, by performing the initialization for the sequence circuits 22 and 23 which are provided at the pre-stage of the combination circuit 25, the output of the combination circuit 25 can be determined irrespective of the output of the pre-stage combination circuit 24.

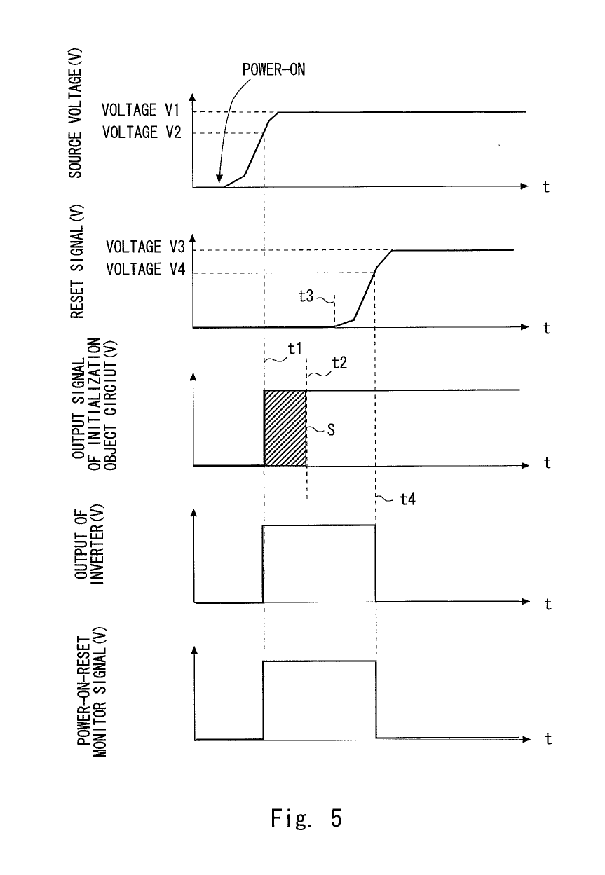

Hereinafter, operation of the semiconductor integrated circuit 100 configured as described above will be explained. FIG. 5 is a schematic diagram showing a relation between time and voltage for each of a source voltage, the reset signal Sᵣ, the output signal Sₒ of the initialization object circuit 12, an output signal of the inverter 131, and the power-on-reset monitor signal Sₘ.

When it is detected that the source voltage supplied to the semiconductor integrated circuit 100 reaches a predetermined voltage V2 after power is supplied to the semiconductor integrated circuit 100, the power-on-reset circuit 11 generates the Low level signal and outputs it to the initialization object circuit 12. This Low level signal is the reset signal Sᵣ.

Because the source voltage becomes higher after power is applied to the semiconductor integrated circuit 100, devices in the semiconductor integrated circuit 100 start to operate at time t1. How the source voltage rises is determined by the output of the voltage supply source and a load capacitance (not shown) connected between the output of the power source supply and the ground. Time t1 represents the time required for supplying a steady voltage represented by a voltage V2a when the load capacitance is charged. Time t1 represents also the time required for the inverter 131 to perform normally as the logic gate.

At time t1, when the logic gate functions normally, the reset terminals RB of the sequence circuits 21 to 23 receive the reset signal Sᵣ of Low level. As shown in the truth table of FIG. 3, when the Low level signal Sᵣ is received, the sequence circuits 21 to 23 output Low level signals from the output terminals Q. Generally, it takes a specified time for the reset function to become active from when the reset terminal RB receives the Low level signal. This is because of a characteristic of semiconductor. Hereinafter, the time when the reset operation becomes active is referred as time t2.

Until time t2, the reset signal Sᵣ does not become active, and the output signal Sₒ of the initialization object circuit 12 is likely to be unsteady as denoted by S. That is, the condition in which the output voltage Sₒ has both states of Low and High levels occurs until time t2.

Voltage of the reset signal Sᵣ begins to rise from Low level at time t3, and reaches a voltage V4 at time t4. The voltage t4 represents a voltage which the logic gate recognizes as High level. The reset signal Sᵣ further rises to a voltage V3, and is stabilized at the voltage V3.

The output signal of the inverter 131 is an inverted signal of the reset signal Sᵣ, and becomes High level at time t1 after power-on. The output signal of the inverter 131 is inverted and becomes Low level at time t4 when the reset signal Sᵣ reaches the voltage V4.

A period between time t3 and time t4 is adequately long, and is sufficient to complete the setting of the initial value for the initialization object circuit 12. The power-on-reset monitor signal Sₘ is in the same state as that of the output signal of the inverter 131 irrespective of the output signal Sₒ including an unsteady condition S, because the power-on-reset monitor signal Sₘ represents a logical sum between the output signal of the inverter 131 and the output signal Sₒ of the initialization circuit 12.

The initialization for the initialization object circuit 12 is completed at time t4. After time t4, the output of the power-on-reset circuit 11 becomes High level. The initialization object circuit 12 shifts to a normal operation state. After time t4, the power-on-reset monitor signal Sₘ keeps Low level until the initialization object circuit 12 further receives the reset signal Sᵣ from outside of the initialization object circuit 12.

The power-on-reset monitor signal Sₘ according to the first exemplary embodiment depends on not only the reset signal Sᵣ but also the output signal Sₒ of the initialization object circuit 12. Even if the power-on-reset monitor signal Sₘ is monitored, the state of the reset signal Sᵣ cannot be detected accurately under such a situation that the initialization object circuit 12 is broken down, for example. However, even if the initialization object circuit 12 is broken down, the state of the reset signal Sᵣ can be detected based on the power-on-reset monitor signal Sₘ as described below.

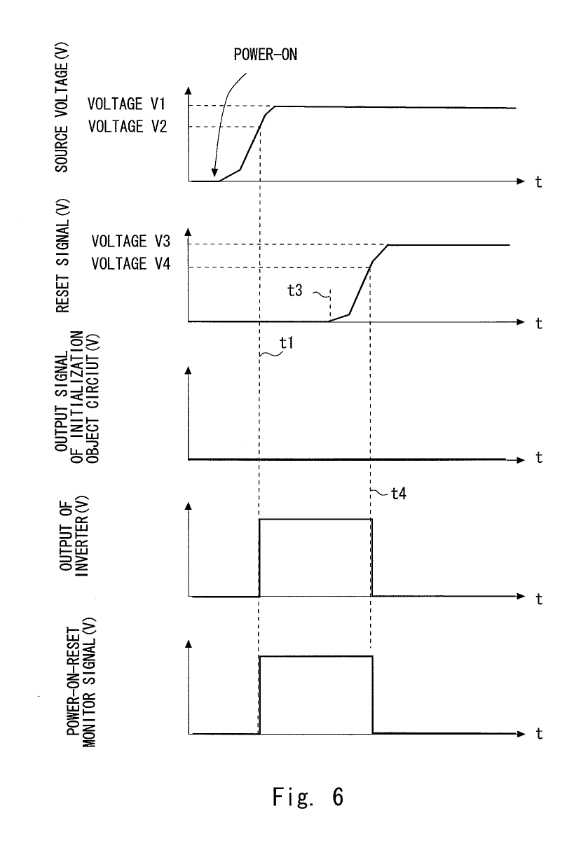

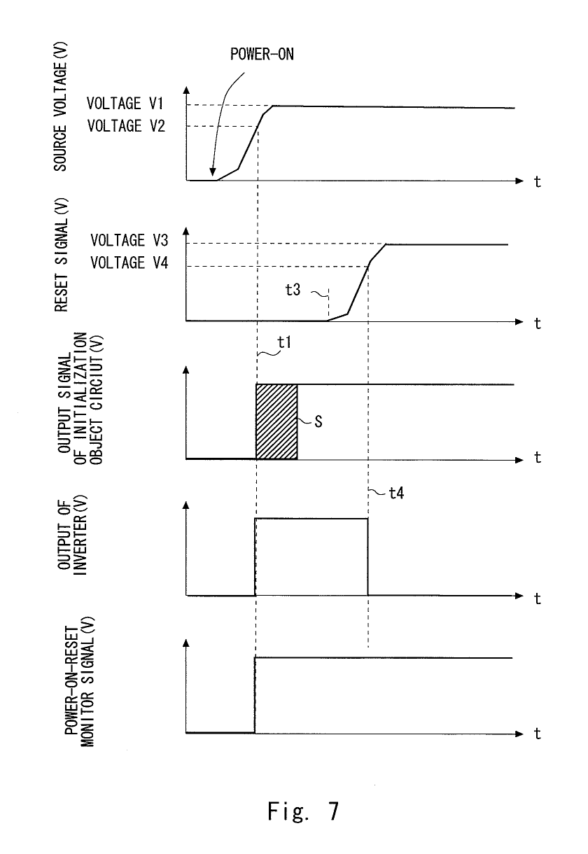

FIGS. 6 and 7 are diagrams showing the state of the power-on-reset monitor signal Sₘ in the case that the sequence circuit 21 included in the initialization object circuit 12 is broken. The initialization object circuit 12 (the sequence circuit 21) is broken in the two situations. One situation is that the output signal Sₒ of the sequence circuit 21 keeps Low level as shown in FIG. 6. Another situation is that the state of the output signal Sₒ of the sequence circuit 21 keeps High as described in FIG. 7.

FIG. 6 is schematic timing chart showing a relation between time and voltage in each signal in the case that the output signal Q of the initialization object circuit 12 (the sequence circuit 21) keeps Low level, and the initialization object circuit 12 (the sequence circuit 21) does not operate normally even after an elapse of a predetermined initialization time is passed. Each signal as shown in FIGS. 6 and 7 is corresponds to each signal shown in FIG. 5.

When the output signal Q of the sequence circuit 21 keeps Low level, the output signal Sₒ of the initialization object circuit 12 does not become the unsteady condition S shown in FIG. 5 and keeps Low level. In this case, the power-on-reset monitor signal Sₘ is in the same state as the inverted signal of the reset signal Sᵣ. Therefore, the state of the reset signal Sᵣ can be detected by monitoring the power-on-reset monitor signal Sₘ in the case of the normal condition shown in FIG. 5.

FIG. 7 is a schematic timing chart showing a relation between time and voltage in each signal in the case that the output signal Sₒ of the initialization object circuit 12 (the sequence circuit 21) keeps High level, and the initialization object circuit 12 (the sequence circuit 21) does not operate normally even after an elapse of a predetermined initialization time. As shown in FIG. 7, when time reaches time t1 after the power-on, the output signal Sₒ of the initialization object circuit 12 keeps High level. Therefore, the power-on-reset monitor signal Sₘ keeps High level from time t1 irrespective of the state of the reset signal Sᵣ.

In this state, the state of the reset signal Sᵣ cannot be monitored by monitoring the power-on-reset monitor signal Sₘ. However, when the semiconductor integrated circuit provides more than two output function terminals 14, and is configured so that output function terminals other than for the output function terminals having a function of monitoring the power-on-reset can be operated, it can be determined whether the initialization object circuit 12 is broken or the power-on-reset circuit 11 is broken. That is, when the other output function terminals function normally, it can be determined that the reset condition is released. Consequentially, it can be detected that the initialization object circuit 12 is broken.

In this way, in the semiconductor integrated circuit 100 according to the first exemplary embodiment of the invention, the state of each of the reset signal Sᵣ and the output signal Sₒ can be monitored by monitoring the power-on-reset monitor signal Sₘ from outside of the semiconductor integrated circuit 100. This is because the power-on-reset monitor signal Sₘ is generated based on the reset signal Sᵣ output from the power-on-reset circuit 11 and the output signal Sₒ of the initialization object circuit 12. Consequentially, it can be judged easily whether the defect is caused due to a defect of the power-on-reset circuit 11 or a defect of the initialization object circuit 12. Because a logical sum between the reset signal Sᵣ and the output signal Sₒ is output as the power-on-reset monitor signal Sₘ, it is not necessary to provide a selector and a function to receive a test signal for selecting an output of the selector, unlike conventional art. With this omitting of the selector and the received function, scale down of the circuit size can be obtained.

In the conventional circuit, in consideration of a difference of signal delay of the reset signal for each circuit included in the initialization object circuit, which is caused due to fabrication variation, judge circuits judging whether or not the initialization for each circuit is finished are provided for the some places where the signal delay is presumed maximum. After all the judge circuits judge that the initialization is completed, the reset signal is cancelled.

That is, in the conventional circuit, some judge circuits for judging whether or not the initialization is finished are provided for one initialization object circuit. Nowadays, with improvement of fabrication variation, steady fabrication of capacitance elements can be realized. Under the circumstance, when some judge circuits are provided for judging whether or not the initialization is finished, the semiconductor integrated circuit is increased in size, and the circuit configuration is complicated, whereby a defect is liable to occur.

On the other hand, in the semiconductor integrated circuit 100 according to this exemplary embodiment, at least one of the power-on-reset monitor circuits 13 may be provided for the initial setting object circuit 12. Accordingly, the circuit configuration for monitoring whether or not the initialization is performed normally from outside of the semiconductor integrated circuit can be omitted. As a result, the circuit scale can be greatly reduced.

In this exemplary embodiment, the semiconductor integrated circuit 100 is configured so that the power-on-reset monitor circuit 13 receives the output signals Q of the sequence circuits 21 to 23. However, as long as the output of the combination circuit provided at the subsequent stage of the sequence circuits 21 to 23 is determined depending on the output signals Q, the power-on-reset monitor circuit 13 may receive the output of the subsequent-stage combination circuit. In this way, even when the power-on-reset circuit 13 does not receive the output of the sequence circuits directly, the same result as that obtained when the power-on-reset monitor circuit 13 receives the output of the sequence circuits can be obtained upon reception of the output of the sequence circuits through the subsequent-stage combination circuit.

### Second Exemplary Embodiment

Hereinafter, a configuration of a semiconductor integrated circuit 200 according to a second exemplary embodiment of the invention will be described. One aspect of the second exemplary embodiment is that the circuit is configured so that the reset signal Sᵣ can be monitored, even if an output function terminal to which an initialization object circuit 83 is connected is set to High level or High impedance by the initialization. Another aspect of the second exemplary embodiment is that a plurality of power-on-reset monitor circuits 13 and 81 are provided for one initialization object circuit 83.

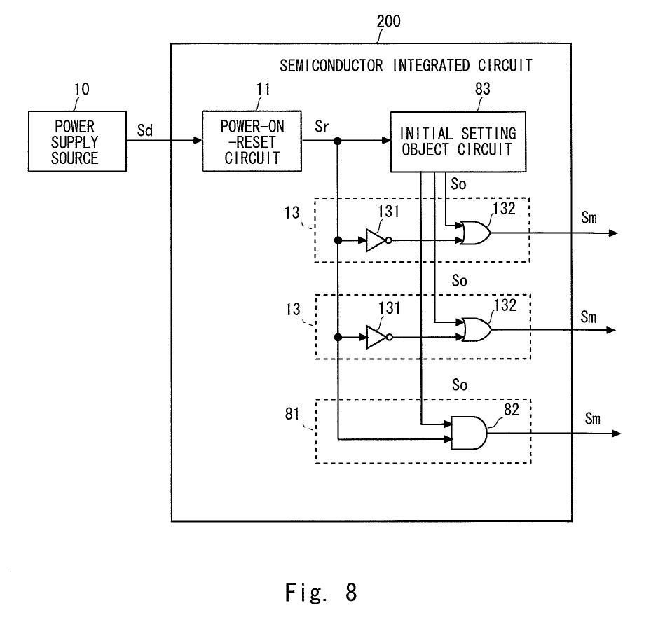

FIG. 8 shows an exemplary overall configuration of the semiconductor integrated circuit 200 according to the second exemplary embodiment of the present invention. In the semiconductor integrated circuit 200 includes the plurality of power-on-reset monitor circuits 13 and 81 for one initialization object circuit 83. An explanation for the power-on-reset monitor circuit 13 is omitted because the configuration thereof is approximately the same as that the first exemplary embodiment.

The power-on-reset monitor circuit 81 is a circuit to monitor the reset signal Sᵣ in the case that the output function terminal C connected to the power-on-reset monitor circuit 81 is connected to a terminal which is set to High level or High impedance at the initialization. The power-on-reset monitor circuit 81 is configured to provide a logical AND circuit 82. The logical AND circuit 82 receives the reset signal Sᵣ output from the power-on-reset circuit 11 and the output signal Sₒ of a sequence circuit included in the initialization object circuit 83. The power-on-reset monitor circuit 81 performs logical multiplication between the reset signal Sᵣ and the output signal Sₒ, and outputs the multiplied value to the output function terminal C.

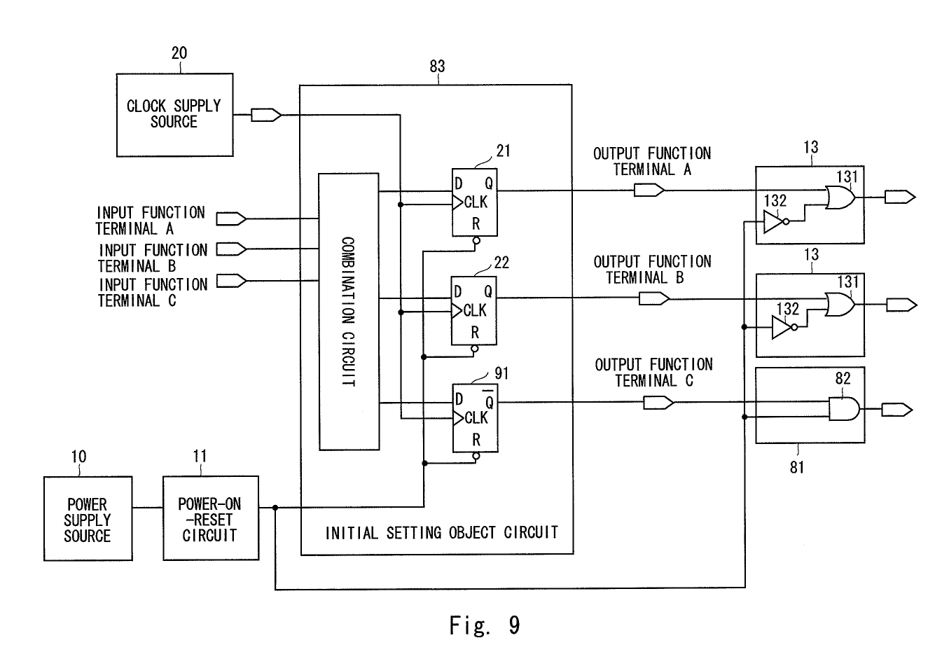

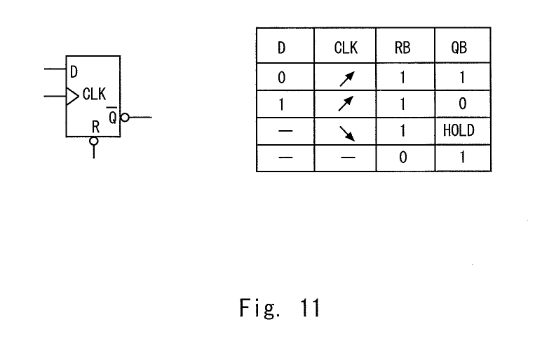

FIG. 9 shows a specific configuration around the initialization object circuit provided in the semiconductor integrated circuit 200 shown in FIG. 8. The logical AND circuit 83 has a plurality of the sequence circuits 21, 22, and 91. As shown in FIG. 3, the sequence circuits 21 and 22 are the flip-flop circuits which are configured as to output a Low level output signal to the subsequent-stage circuits by initialization. The terminals of the sequence circuit 91 and the truth table thereof are shown in FIG. 11. That is, an output signal QB of the sequence circuit 91 is an inverted signal of the output signal Q shown in FIG. 3.

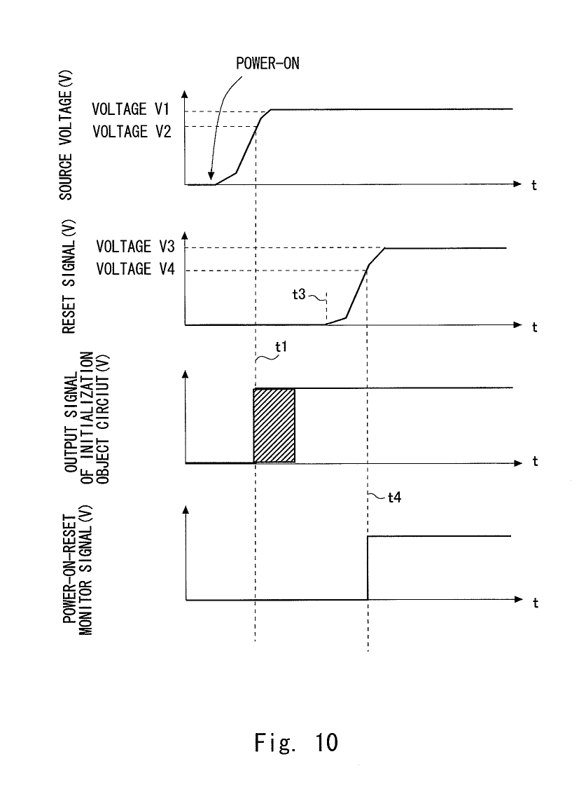

Next, operation of the power-on-reset monitor circuit 81 will be explained. FIG. 10 is a diagram for explaining the state of the power-on-reset monitor signal Sₘ output from the power-on-reset monitor circuit 81. In FIG. 11, explanation for the voltages V1 to V4, times t1 to t4, and the unsteady condition S are omitted because they are already explained in the first exemplary embodiment.

At time t1, the source voltage begins to rise. Until time t2, the output of the sequence circuit 91 is under the unsteady condition S in which voltage cannot be settled to Low or High level. The output signal QB of the sequence circuit 91 becomes High when Low level voltage is supplied to the reset signal Sᵣ as shown in FIG. 11. Accordingly, when the sequence circuit 91 functions normally, the output signal QB of the sequence circuit 91 becomes High.

The power-on-reset monitor signal Sₘ which is the output signal of the power-on-reset monitor circuit 81 outputs a logical multiplication between the reset signal Sᵣ of the power-on reset circuit 11 and the output signal Sₒ of the sequence circuit 91. That is, the power-on-reset monitor signal Sₘ does not depend on the output signal Sₒ (QB), is in the same stage as that of the reset signal Sᵣ output from the power-on-reset circuit 11.

In this way, in the second exemplary embodiment, the power-on-reset monitor signal Sₘ is generated with performing the logical multiplication between the reset signal Sᵣ and the output signal Sₒ of the sequence circuit 91. Consequently, even if the sequence circuit 91 is set to High level or High impedance at the initialization, the reset signal Sr can be monitored.

In the first exemplary embodiment, the power-on-reset monitor signal Sₘ is generated for the initialization object circuit in which the output of the sequence circuits is set to Low level at the initialization by performing logical addition between the inverted signal of the reset signal Sᵣ and a connection signal of the output terminal of the logic circuit including the sequence circuits. In the above case, when the initialization object circuit including the sequence circuits has a defect, the connection signal for the output function terminal keeps High level and cannot be initialized. Consequently, because the power-on-reset signal is logical addition of High level, the state of the output function terminal is constantly High level. The case may occur in which the reset signal Sᵣ cannot be monitored. On the other hand, in the second exemplary embodiment, the plurality of power-on-reset monitor circuits 13 and 81 are provided for one initialization object circuit 83, and thus a defect position can be detected reliably.

The first and second exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor integrated circuit comprising:
a power-on-reset circuit that outputs a reset signal based on a detect signal representing that power is applied to the semiconductor integrated circuit;
at least one initialization object circuit for which an initialization is performed based on the reset signal; and
at least one power-on-reset monitor circuit that generates and outputs a power-on-reset monitor signal based on the reset signal output from the power-on-reset circuit and an output signal of the initialization object circuit for which the initialization is performed, the power-on-reset monitor signal representing whether or not the initialization is performed normally.

2. The semiconductor integrated circuit according to claim 1, wherein the at least one power-on-reset monitor circuit comprises a plurality of the power-on-reset monitor circuits, wherein
the plurality of the power-on-reset monitor circuits are provided for one of the at least one initialization setting circuit.

3. The semiconductor integrated circuit according to claim 1, wherein
the power-on-reset monitor circuit comprises an inverter and a logical OR circuit,
the inverter inverts the reset signal received from the power-on-reset circuit and outputting an inverted signal,
one terminal of the logical OR circuit receives the output of the inverter, and another terminal of the logical OR circuit receives the output signal output from the initialization object circuit, and
the logical OR circuit performs logical addition between the reset signal and the output signal and outputs an added value as the power-on-reset monitor signal.

4. The semiconductor integrated circuit according to claim 1, wherein
the power-on-reset monitor circuit comprises a logical AND circuit,
one terminal of the logical AND circuit receives the reset signal output from the power-on-reset circuit, and another terminal of the logical AND circuit receives the output signal output from the initialization object circuit, and
the logical AND circuit performs logical multiplication between the reset signal and the output signal and outputs a multiplied value as the power-on-reset monitor signal.

5. The semiconductor integrated circuit according to claim 1, wherein the initialization object circuit comprises a sequence circuit whose output is determined based on a state of the reset signal.

6. The semiconductor integrated circuit according to claim 5, wherein the output signal of the initialization object circuit is the output of the sequence circuit.

7. The semiconductor integrated circuit according to claim 6, the power-on-reset monitor circuit receives the output of the sequence circuit through a combination circuit included in the initialization object circuit.

8. The semiconductor integrated circuit according to claim 5, wherein the sequence circuit comprises at least one of a flip-flop circuit, a latch circuit, a counter, and a register.

9. A control method of a semiconductor integrated circuit comprising:
detecting that power is applied to the semiconductor integrated circuit;
performing an initialization for an initialization object circuit by outputting a reset signal, the initialization object circuit being subjected to the initialization;
generating a power-on-reset monitor signal based on the reset signal and an output signal of the initialization object circuit to which an initial value is set, the power-on-reset monitor signal representing whether or not the initialization is performed normally; and
outputting the generated power-on-reset monitor signal.
